(19) United States
(12) Patent Application Publication
(10) Pub. No.: US 2025/0356921 A1
(43) Pub. Date: Nov. 20, 2025

(54) MEMORY DEVICE AND METHOD OF OPERATING THE MEMORY DEVICE

(71) Applicant: SK hynix Inc., Icheon-si Gyeonggi-do (KR)

(72) Inventor: In Seob NOH, Icheon-si Gyeonggi-do (KR)

(73) Assignee: SK hynix Inc., Icheon-si Gyeonggi-do (KR)

(21) Appl. No.: 18/955,619

(22) Filed: Nov. 21, 2024

(30) Foreign Application Priority Data
May 14, 2024 (KR) 10-2024-0063180

(51) Int. Cl. G11C 16/10; G11C 16/04; G11C 16/08; G11C 16/30

(52) U.S. Cl. CPC G11C 16/10; G11C 16/08; G11C 16/30; G11C 16/0483

(57) ABSTRACT

Provided herein is a memory device and a method of operating the memory device. The memory device includes a memory block including a plurality of memory cells connected to a plurality of word lines, respectively, a peripheral circuit configured to perform a test program operation and a pass bit detection operation of measuring a program speed of memory cells connected to a selected word line among the plurality of word lines during a test operation, and control logic configured to control the peripheral circuit to perform the test operation, and set a potential of a pass voltage to be used in a program operation, or a time point at which the pass voltage is to be applied, based on a number of times the test program operation is performed.

### CROSS-REFERENCE TO RELATED APPLICATION

The present application claims priority under 35 U.S.C. § 119(a) to Korean patent application number 10-2024-0063180 filed on May 14, 2024, in the Korean Intellectual Property Office, the entire contents of which application is incorporated herein by reference.

### BACKGROUND

### 1. Technical Field

Various embodiments of the present disclosure relate to an electronic device, and more particularly to a memory device and a method of operating the memory device.

### 2. Related Art

Memory devices are storage devices implemented using a semiconductor such as silicon (Si), germanium (Ge), gallium arsenide (GaAs), or indium phosphide (InP). The memory devices are largely classified into a volatile memory device and a nonvolatile memory device.

The volatile memory device is a memory device in which data stored therein is lost when power supply is interrupted. Representative examples of the volatile memory device include a static random access memory (SRAM), a dynamic RAM (DRAM), a synchronous DRAM (SDRAM), etc. The nonvolatile memory device is a memory device in which data stored therein is retained even when power supply is interrupted. Representative examples of the nonvolatile memory device include a read only memory (ROM), a programmable ROM (PROM), an electrically programmable ROM (EPROM), an electrically erasable programmable ROM (EEPROM), a flash memory, a phase-change RAM (PRAM), a magnetic RAM (MRAM), a resistive RAM (RRAM), a ferroelectric RAM (FRAM), etc. The flash memory is largely classified into a NOR type and a NAND type.

### SUMMARY

An embodiment of the present disclosure may provide for a memory device. The memory device may include a memory block including a plurality of memory cells connected to a plurality of word lines, respectively, a peripheral circuit configured to perform a test program operation and a pass bit detection operation of measuring a program speed of memory cells connected to a selected word line among the plurality of word lines during a test operation, and control logic configured to control the peripheral circuit to perform the test operation, and set a potential of a pass voltage to be used in a program operation, or a time point at which the pass voltage is to be applied, based on a number of times the test program operation is performed.

An embodiment of the present disclosure may provide for a method of operating a memory device. The method may include performing a test program operation on a selected word line among a plurality of word lines of a memory block, detecting a number of pass bits corresponding to memory cells having threshold voltages equal to or higher than a set threshold voltage among memory cells connected to the selected word line by performing a pass bit detection operation, when the number of pass bits is less than a set value, re-performing the test program operation using a new program voltage, and when the number of pass bits is equal to or greater than the set value, setting a level of a pass voltage to be used in a program operation or a time point at which the pass voltage is to be applied, based on a number of times the test program operation is performed.

An embodiment of the present disclosure may provide for a method of operating a memory device. The method may include performing a test program operation on a selected word line among a plurality of word lines of a memory block, detecting a number of pass bits corresponding to memory cells having threshold voltages equal to or higher than a set threshold voltage among memory cells connected to the selected word line by performing a pass bit detection operation, when the number of pass bits is less than a set value, resetting a potential of a pass voltage to be applied to word lines adjacent to the selected word line or a time point at which the pass voltage is to be applied, and re-performing the test program operation, and when the number of pass bits is equal to or greater than the set value, setting a level of a pass voltage to be used in a program operation or a time point at which the pass voltage is to be applied, based on a number of times the test program operation is performed.

### BRIEF DESCRIPTION OF THE DRAWINGS

FIG. 1 is a diagram for explaining a memory system including a memory device according to an embodiment of the present disclosure.

FIG. 2 is a diagram for explaining the structure of the memory device of FIG. 1.

FIG. 3 is a block diagram illustrating an embodiment of a memory cell array of FIG. 2.

FIG. 4 is a circuit diagram illustrating any one of memory blocks of FIG. 3.

FIG. 5 is a circuit diagram illustrating an embodiment of any one of memory blocks of FIG. 3.

FIG. 6 is a circuit diagram illustrating an embodiment of any one of a plurality of memory cells included in the memory cell array of FIG. 2.

FIG. 7 is a flowchart for explaining the operation of a memory device according to an embodiment of the present disclosure.

FIG. 8 is a waveform diagram of signals for explaining a program voltage apply operation among operations of a memory device according to an embodiment of the present disclosure.

FIG. 9 is a threshold voltage distribution diagram for explaining the threshold voltages of memory cells after a test program operation.

FIG. 10 is a flowchart for explaining the operation of a memory device according to an embodiment of the present disclosure.

FIG. 11 is a diagram for explaining a memory controller of FIG. 1.

FIG. 12 is a block diagram illustrating a memory card system to which a memory system according to an embodiment of the present disclosure is applied.

FIG. 13 is a block diagram illustrating a solid state drive (SSD) system to which a memory system according to an embodiment of the present disclosure is applied.

FIG. 14 is a block diagram illustrating a user system to which a memory system according to an embodiment of the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a memory device and a method of operating the memory device, which can compensate for variations in the program speed of memory cells.

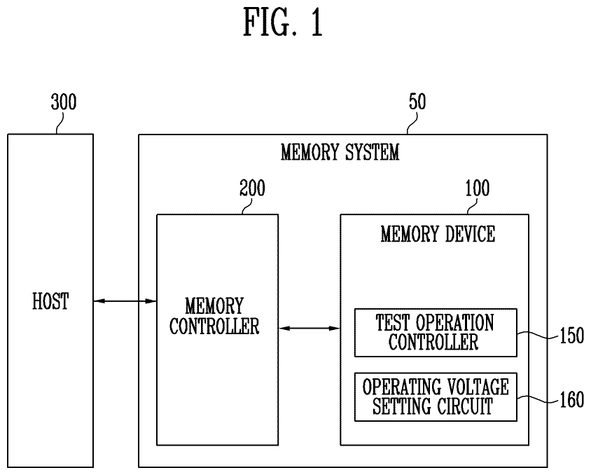

FIG. 1 is a diagram for explaining a memory system including a memory device according to an embodiment of the present disclosure.

Referring to FIG. 1, a memory system 50 may include a memory device 100 and a memory controller 200. The memory system 50 may be a device which stores data under the control of a host 300, such as a mobile phone, a smartphone, an MP3 player, a laptop computer, a desktop computer, a game console, a television (TV), a tablet PC, or an in-vehicle infotainment system.

The memory system 50 may be manufactured as any one of various types of storage devices depending on a host interface that is a scheme for communication with the host 300. For example, the memory system 50 may be implemented as any one of various types of storage devices, for example, a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-E) card-type storage device, a compact flash (CF) card, a smart media card, and a memory stick.

The memory system 50 may be manufactured in any one of various types of package forms. For example, the memory system 50 may be manufactured in any one of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may operate in response to the control of the memory controller 200. The memory device 100 may include a memory cell array (not illustrated) including a plurality of memory cells which store data.

Each of the memory cells may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

The memory cell array (not illustrated) may include a plurality of memory blocks. Each memory block may include a plurality of memory cells. One memory block may include a plurality of pages. In an embodiment, each page may be the unit by which data is stored in the memory device 100 or by which data stored in the memory device 100 is read. A memory block may be the unit by which data is erased.

In an embodiment, the memory device 100 may be a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM), a NAND flash memory, a vertical NAND flash memory, a NOR flash memory, a resistive RAM (RRAM), a phase-change random access memory (PRAM), a magnetoresistive RAM (MRAM), a ferroelectric RAM (FRAM), a spin transfer torque RAM (STT-RAM), or the like. In the present specification, for convenience of description, description will be made on the assumption that the memory device 100 is a NAND flash memory.

The memory device 100 may receive a command and an address from the memory controller 200, and may access the area of the memory cell array, selected by the address. The memory device 100 may perform an operation indicated by the command on an area selected by the address. For example, the memory device 100 may perform a write operation (program operation), a read operation, and an erase operation. During a write operation, the memory device 100 may program data to the area selected by the address. During a read operation, the memory device 100 may read data from the area selected by the address. During an erase operation, the memory device 100 may erase data stored in the area selected by the address.

The program operation may be an operation of storing data in memory cells. In detail, the program operation may be an operation of increasing the threshold voltages of memory cells depending on data to be stored in the memory cells. When the program operation is performed, each of the memory cells may have a threshold voltage corresponding to any one of a plurality of program states. The plurality of program states may be may be determined depending on the number of data bits stored in one memory cell. For example, when the memory cells are programmed according to the TLC scheme in which one memory cell stores three bits of data, the plurality of program states may indicate first to seventh program states. After the program operation is performed, the threshold voltages of the memory cells may be determined depending on the data to be stored in the memory cells. Each of the memory cells may have any one of the plurality of program states as a target program state depending on the data to be stored therein.

In an embodiment, the program operation may include a program voltage apply operation and a verify operation. The program voltage apply operation may be an operation of increasing the threshold voltages of memory cells using a program voltage. The verify operation may be an operation of verifying whether the threshold voltages of the memory cells have reached threshold voltages corresponding to target program states using a verify voltage.

In an embodiment, the program voltage apply operation may apply the program voltage to a selected word line and apply a pass voltage to unselected word lines. A first pass voltage and a second pass voltage, having a potential higher than that of the first pass voltage, may be sequentially applied to word lines adjacent to the selected word line among the unselected word lines, and the first pass voltage may be applied to the remaining unselected word lines.

In an embodiment, when the number of memory cells, the threshold voltages of which have not reached threshold voltages corresponding to the target program states, is equal to or greater than a set number during a verify operation, the above-described program voltage apply operation and verify operation may be re-performed by increasing the program voltage by a step voltage.

In an embodiment, the memory controller 100 may include a test operation controller 150 and an operating voltage setting circuit 160.

The test operation controller 150 may control a test operation of determining the program speed of memory cells. The test operation may include a test program operation performed on memory cells in an erase state and a pass bit detection operation. During the test program operation, the threshold voltages of the memory cells may increase due to the program voltage, and during the pass bit detection operation, memory cells having threshold voltages equal to or higher than a set threshold voltage may be detected among memory cells on which the test program operation has been performed, and whether the number of detected memory cells is equal to or greater than a set value may be determined. The number of memory cells having threshold voltages equal to or higher than the set threshold voltage may be defined as the number of pass bits. When the number of pass bits is less than the set value, the test program operation and the pass bit detection operation may be re-performed, or in other words, the test program operation and the pass bit detection operation are performed again and the number of pass bits are detected to determine if the number of pass bits are less than the set value or are equal to or greater than the set value. When the number of detected pass bits is equal to or greater than the set value, the test operation may be completed.

The operating voltage setting circuit 160 may perform an operating voltage setting operation of setting the program voltage and the pass voltage required for compensating for the program speed of the memory cells after the test operation is completed. After the test operation is completed, the operating voltage setting circuit 160 may determine the program speed of the memory cells based on the number of test program operations that are repeatedly performed until the test operation is completed. For example, the operating voltage setting circuit 160 may determine that the program speed is slower as the number of test program operations is larger, and may determine that the program speed is faster as the number of test program operations is smaller. For example, when it is determined that the program speed of selected memory cells is relatively fast as a result of the test operation, the operating voltage setting circuit 160 may set a start program voltage by decreasing the potential of the start program voltage to be used in a first program voltage apply operation, among program voltages to be used in the program operation, from an initial value by a set value. Also, the operating voltage setting circuit 160 may set the second pass voltage to be applied to word lines adjacent to the selected word line by decreasing the potential of the second pass voltage from an initial value by a set value during the program operation. Furthermore, the operating voltage setting circuit 160 may set a time point at which the second pass voltage is to be applied to the word lines adjacent to the selected word line by delaying the time point from an initial time point by a set time during the program operation.

When it is determined that the program speed of the selected memory cells is relatively slow as a result of the test operation, the operating voltage setting circuit 160 may set the start program voltage by increasing the potential of the start program voltage from the initial value by the set value. In addition, the operating voltage setting circuit 160 may set the second pass voltage to be applied to the word lines adjacent to the selected word line by increasing the potential of the second pass voltage from the initial value by the set value during the program operation. Furthermore, the operating voltage setting circuit 160 may set a time point at which the second pass voltage is to be applied to the word lines adjacent to the selected word line by advancing the time point from the initial time point by the set time during the program operation.

The above-described test operation and operating voltage setting operation may be performed on a word line basis, a word line group (including a plurality of word lines) basis, a memory block basis, a plane (including a plurality of memory blocks) basis, a die basis, or the like.

The memory controller 200 may control the overall operation of the memory system 50.

When power is applied to the memory system 50, the memory controller 200 may run firmware (FW). When the memory device 100 is a flash memory device, the firmware (FW) may include a host interface layer (HIL) which controls communication with the host 300, a flash translation layer (FTL) which controls communication between the host 300 and the memory device 100, and a flash interface layer (FIL) which controls communication with the memory device 100.

In an embodiment, the memory controller 200 may receive data and a logical block address (LBA) from the host 300, and may translate the logical block address (LBA) into a physical block address (PBA) indicating the address of memory cells which are included in the memory device 100 and in which data is to be stored. In the present specification, a logical block address (LBA) and a “logical address” may be used interchangeably with each other. In the present specification, a physical block address (PBA) and a “physical address” may be used interchangeably with each other.

The memory controller 200 may control the memory device 100 to perform a program operation, a read operation or an erase operation is performed in response to a request received from the host 300. During a write operation, the memory controller 200 may provide a write command, a physical block address, and data to the memory device 100. During a read operation, the memory controller 200 may provide a read command and a physical block address to the memory device 100. During an erase operation, the memory controller 200 may provide an erase command and a physical block address to the memory device 100.

In an embodiment, the memory controller 130 may independently generate a command, an address, and data regardless of whether a request from the host 300 is received, and may transmit them to the memory device 100. For example, the memory controller 200 may provide the memory device 100 with commands, addresses, and data which are required for performing read operations and program operations associated with performance of wear leveling, read reclaim, garbage collection, etc.

In an embodiment, the memory controller 200 may control at least two memory devices 100. In this case, in an embodiment, the memory controller 200 may control the memory devices 100 depending on an interleaving scheme to improve operating performance. The interleaving scheme may be a scheme for controlling the memory devices 100 so that the operations of at least two memory devices 100 are caused to overlap each other.

The host 300 may communicate with the memory system 50 using at least one of various communication methods such as universal serial bus (USB), serial AT attachment (SATA), serial attached SCSI (SAS), high speed Interchip (HSIC), small computer system Interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

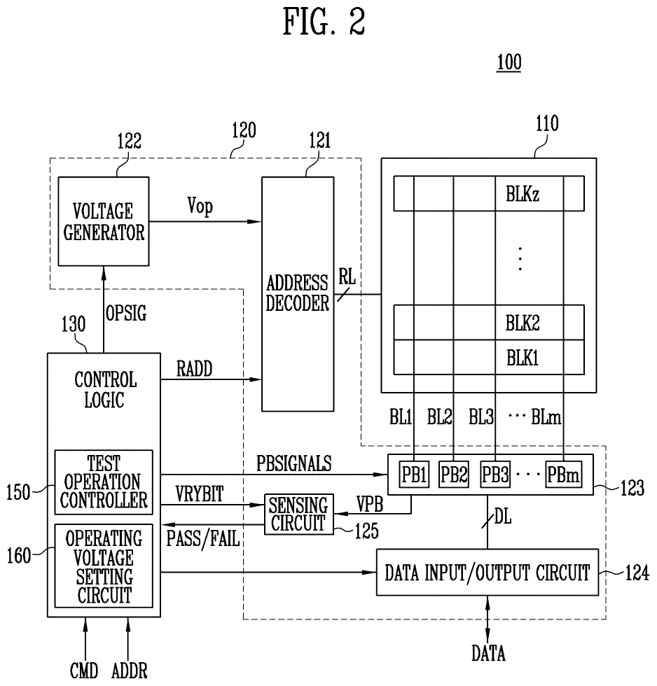

FIG. 2 is an embodiment of a diagram for explaining the structure of the memory device of FIG. 1.

Referring to FIG. 2, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz may be connected to a page buffer group 123 through bit lines BL1 to BLm. Each of the memory blocks BLK1 to BLKz may include a plurality of memory cells. In an embodiment, the plurality of memory cells may be nonvolatile memory cells. Memory cells connected to the same word line among the plurality of memory cells are defined as one page. In other words, the memory cell array 110 may be composed of a plurality of pages. In accordance with an embodiment of the present disclosure, each of the memory blocks BLK1 to BLKz included in the memory cell array 110 may include a plurality of dummy cells. For the dummy cells, one or more dummy cells may be connected in series between a drain select transistor and memory cells and between a source select transistor and memory cells.

Each of the memory cells of the memory device 100 may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

At least one of the plurality of memory blocks BLK1 to BLKz may be defined as a system block or a content addressable memory (CAM) block. In the memory block defined as the system block or the CAM block, information about a start program voltage that is set after the test operation, information about the level of a second pass voltage, or information about a time point at which the second pass voltage is to be applied may be stored.

The peripheral circuit 120 may drive the memory cell array 110. In an example, the peripheral circuit 120 may drive the memory cell array 110 to perform a program operation, a read operation, and an erase operation under the control of the control logic 130. In an example, the peripheral circuit 120 may apply various operating voltages to the row lines RL and the bit lines BL1 to BLm or discharge the applied voltages under the control of the control logic 130.

Further, the peripheral circuit 120 may drive the memory cell array 110 to perform a test program operation on a selected word line of a selected memory block and a pass bit detection operation on the selected word line during a test operation.

The peripheral circuit 120 may include the address decoder 121, a voltage generator 122, the page buffer group 123, a data input/output circuit 124, and a sensing circuit 125.

The address decoder 121 is connected to the memory cell array 110 through the row lines RL. The row lines RL may include drain select lines, word lines, source selection lines, and a common source line. In accordance with an embodiment of the present disclosure, the word lines may include normal word lines and dummy word lines. In accordance with an embodiment of the present disclosure, the row lines RL may further include a pipe select line.

The address decoder 121 may be operated under the control of the control logic 130. The address decoder 121 receives addresses ADDR from the control logic 130 (not shown).

The address decoder 121 may decode a block address among the received addresses ADDR. The address decoder 121 may select at least one of the memory blocks BLK1 to BLKz according to the decoded block address. The address decoder 121 may decode a row address RADD among the received addresses ADDR. The address decoder 121 may select at least one word line WL of the selected memory block by applying voltages supplied from the voltage generator 122 to the at least one word line WL according to the decoded row address RADD.

During the test program operation of the test operation, the address decoder 121 may apply a program voltage to the selected word line, may sequentially apply a first pass voltage and a second pass voltage to word lines adjacent to the selected word line, among the unselected word lines, and may apply the first pass voltage to the remaining unselected word lines.

During the pass bit detection operation of the test operation, the address decoder 121 may apply a set read voltage corresponding to a set threshold voltage to the selected word line, and may apply a read pass voltage to the unselected word lines.

During the program voltage apply operation of the program operation, the address decoder 121 may apply the program voltage to the selected word line, may sequentially apply a first pass voltage and a second pass voltage to word lines adjacent to the selected word line, among the unselected word lines, and may apply the first pass voltage to the remaining unselected word lines. During a program verify operation of the program operation, the address decoder 121 may apply a verify voltage to the selected word line and apply a verify pass voltage having a level higher than that of the verify voltage to the unselected word lines.

During a read operation, the address decoder 121 may apply a read voltage to the selected word line and apply a read pass voltage having a level higher than that of the read voltage to the unselected word lines.

An erase operation of the memory device 100 may be performed on a memory block basis. During the erase operation, addresses ADDR input to the memory device 100 include a block address. The address decoder 121 may decode the block address and select one memory block according to the decoded block address. During the erase operation, the address decoder 121 may apply a ground voltage to word lines connected to the selected memory block.

In accordance with an embodiment of the present disclosure, the address decoder 121 may decode a column address among the received addresses ADDR. The decoded column address may be transferred to the page buffer group 123. In an embodiment, the address decoder 121 may include components, such as a row decoder, a column decoder, and an address buffer.

The voltage generator 122 may generate a plurality of operating voltages Vop using an external supply voltage that is supplied to the memory device 100. The voltage generator 122 may be operated under the control of the control logic 130.

In an embodiment, the voltage generator 122 may generate an internal supply voltage by regulating the external supply voltage. The internal supply voltage generated by the voltage generator 122 may be used as an operating voltage for the memory device 100.

In an embodiment, the voltage generator 122 may generate various operating voltages Vop that are used for program, read, and erase operations in response to an operation signal OPSIG. Also, the voltage generator 122 may generate various operating voltages Vop that are used for the test operation in response to the operation signal OPSIG.

The voltage generator 122 may generate the plurality of operating voltages Vop using the external supply voltage or the internal supply voltage. The voltage generator 122 may generate various voltages required by the memory device 100. For example, the voltage generator 122 may generate a plurality of erase voltages, a plurality of program voltages, the first pass voltage, the second pass voltage, a plurality of verify voltages, the verify pass voltage, a plurality of read voltages, the read pass voltage, and the set read voltage.

The voltage generation unit 122 may include a plurality of pumping capacitors for receiving the internal supply voltage to generate a plurality of operating voltages Vop having various voltage levels, and may generate the plurality of operating voltages Vop by selectively enabling the plurality of pumping capacitors under the control of the control logic 130.

The generated operating voltages Vop may be supplied to the memory cell array 110 by the address decoder 121.

The page buffer group 123 includes first to m-th page buffers PB1 to PBm. The first to m-th page buffers PB1 to PBm are connected to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm may receive data DATA to be stored through the data input/output circuit 124 and data lines DL.

During a program operation, the first to m-th page buffers PB1 to PBm may transfer the data DATA to be stored, received through the data input/output circuit 124, to selected memory cells through the bit lines BL1 to BLm when a program pulse is applied to a selected word line. Memory cells in a selected page may be programmed based on the transferred data DATA. Memory cells connected to a bit line to which a program-enable voltage (e.g., a ground voltage) is applied may have increased threshold voltages. The threshold voltages of memory cells connected to a bit line to which a program-inhibit voltage (e.g., a supply voltage) is applied may be maintained. During a program verify operation, the first to m-th page buffers PB1 to PBm read the data DATA stored in the selected memory cells from the selected memory cells through the bit lines BL1 to BLm.

During a read operation, the page buffer group 123 may read data DATA from the memory cells in a selected page through the bit lines BL, and may store the read data DATA in the first to m-th page buffers PB1 to PBm.

During an erase operation, the page buffer group 123 may allow the bit lines BL to float. In an embodiment, the page buffer group 123 may include a column select circuit.

During the pass bit detection operation, the first to m-th page buffers PB1 to PBm may read data DATA corresponding to the threshold voltages of the selected memory cells through the bit lines BL1 to BLm, and may output a sensing voltage VPB based on the number of specific pieces of data in the read data DATA.

The data input/output circuit 124 is connected to the first to m-th page buffers PB1 to PBm through the data lines DL. The data input/output circuit 124 is operated in response to the control of the control logic 130.

The data input/output circuit 124 may include a plurality of input/output buffers (not illustrated) which receive input data DATA. During a program operation, the data input/output circuit 124 receives the data DATA to be stored from an external controller (not illustrated). During a read operation, the data input/output circuit 124 outputs the data DATA, received from the first to m-th page buffers PB1 to PBm included in the page buffer group 123, to the external controller.

During a read operation, a verify operation or the pass bit detection operation, the sensing circuit 125 may generate a reference current in response to an enable bit signal VRYBIT generated by the control logic 130, and may output a pass signal or a fail signal to the control logic 130 by comparing the sensing voltage VPB received from the page buffer group 123 with a reference voltage generated using the reference current.

The control logic 130 may be connected to the address decoder 121, the voltage generator 122, the page buffer group 123, the data input/output circuit 124, and the sensing circuit 125. The control logic 130 may control the overall operation of the memory device 100. The control logic 130 may be operated in response to a command CMD transmitted from an external device.

The control logic 130 may control the peripheral circuit 120 by generating various types of signals in response to the command CMD and the addresses ADDR. For example, the control logic 130 may generate the operation signal OPSIG, the row address RADD, read and write control signals PBSIGNALS, and the enable bit VRYBIT in response to the command CMD and the addresses ADDR. The control logic 130 may output the operation signal OPSIG to the voltage generator 122, output the row address RADD to the address decoder 121, output the read and write control signals PBSIGNALS to the page buffer group 123, and output the enable bit VRYBIT to the sensing circuit 125. In addition, during a program operation, the control logic 130 may determine whether a verify operation has passed or failed in response to a pass signal PASS or a fail signal FAIL output from the sensing circuit 125. In addition, during the pass bit detection operation, the control logic 130 may determine whether the number of pass bits is equal to or greater than a set value in response to the pass signal PASS or the fail signal FAIL output from the sensing circuit 125.

In an embodiment, the control logic 130 may include a test operation controller 150 and an operating voltage setting circuit 160.

The test operation controller 150 may control the peripheral circuit 120 to perform a test operation of determining the program speed of memory cells. For example, during a test program operation of the test operation, the test operation controller 150 may control the voltage generator 122 to generate the program voltage, the first pass voltage, and the second pass voltage, and may control the address decoder 121 to apply the program voltage to the selected word line, sequentially apply the first pass voltage and the second pass voltage to word lines adjacent to the selected word line, and apply the first pass voltage to the remaining unselected word lines. Further, during the test program operation, the test operation controller 150 may control the page buffer group 123 to apply a program-enable voltage to the plurality of bit lines BL1 to BLm.

For example, during the pass bit detection operation of the test operation, the test operation controller 150 may control the voltage generator 122 to generate the set read voltage and the read pass voltage, and may control the address decoder 121 to apply the set read voltage to the selected word line and apply the read pass voltage to unselected word lines. Furthermore, during the pass bit detection operation, the test operation controller 150 may control the page buffer group 123 to sense the potential or current amount corresponding to the threshold voltages of selected memory cells through the plurality of bit lines BL1 to BLm.

During the pass bit detection operation, the sensing circuit 125 may output the pass signal PASS when the number of memory cells having threshold voltages equal to or higher than the set threshold voltage is equal to or greater than a set value, based on the sensing voltage VPB received from the page buffer group 123, and may output the fail signal FAIL when the number of memory cells having threshold voltages equal to or higher than the set threshold voltage is less than the set value.

The test operation controller 150 may control the peripheral circuit 120 to re-perform or perform again the test program operation and the pass bit detection operation when the fail signal FAIL is received, and may complete the test operation when the pass signal PASS is received.

The operating voltage setting circuit 160 may perform an operating voltage setting operation of setting the program voltage and the pass voltage required for compensating for the program speed of the memory cells after the test operation is completed. After the test operation is completed, the operating voltage setting circuit 160 may determine the program speed of the memory cells based on the number of test program operations that are repeatedly performed until the test operation is completed. For example, the operating voltage setting circuit 160 may determine that the program speed is slower as the number of test program operations is larger, and may determine that the program speed is faster as the number of test program operations is smaller. For example, when it is determined that the program speed of selected memory cells is relatively fast as a result of the test operation, the operating voltage setting circuit 160 may set a start program voltage by decreasing the potential of the start program voltage to be used in a first program voltage apply operation, among program voltages to be used in the program operation, from an initial value by a set value. Also, the operating voltage setting circuit 160 may set the second pass voltage to be applied to word lines adjacent to the selected word line by decreasing the potential of the second pass voltage from an initial value by a set value during the program operation. Furthermore, the operating voltage setting circuit 160 may set a time point at which the second pass voltage is to be applied to the word lines adjacent to the selected word line by delaying the time point from an initial time point by a set time during the program operation.

When it is determined that the program speed of the selected memory cells is relatively slow as a result of the test operation, the operating voltage setting circuit 160 may set the start program voltage by increasing the potential of the start program voltage from the initial value by the set value. In addition, the operating voltage setting circuit 160 may set the second pass voltage to be applied to the word lines adjacent to the selected word line by increasing the potential of the second pass voltage from the initial value by the set value during the program operation. Furthermore, the operating voltage setting circuit 160 may set a time point at which the second pass voltage is to be applied to the word lines adjacent to the selected word line by advancing the time point from the initial time point by the set time during the program operation.

Information about the start program voltage, information about the level of the second pass voltage, or information about the application time point of the second pass voltage for each word line, set by the operating voltage setting circuit 160, may be stored in a memory block defined as a system block or a CAM block among the plurality of memory blocks BLK1 to BLKz.

In an embodiment of the present disclosure, although the potential of the start program voltage, the potential of the second pass voltage, or the application time point of the second pass voltage has been described as being set for each word line, the potential of the start program voltage, the potential of the second pass voltage, or the application time point of the second pass voltage, which corresponds to a word line group including a plurality of word lines, a single memory block, or a plane including a plurality of memory blocks, may be set by defining the plurality of word lines as a single word line group and by calculating the program speed of the word line group, the single memory block, or the plane as an average value.

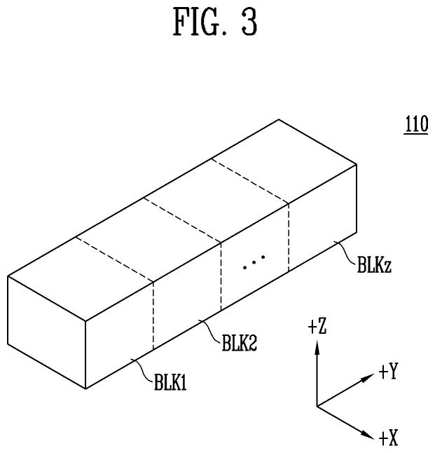

FIG. 3 is a block diagram illustrating an embodiment of a memory cell array of FIG. 2.

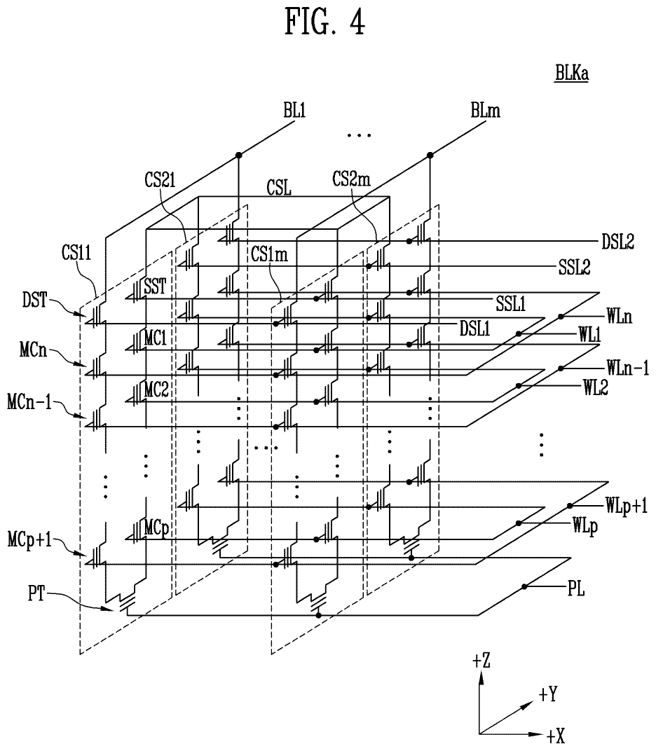

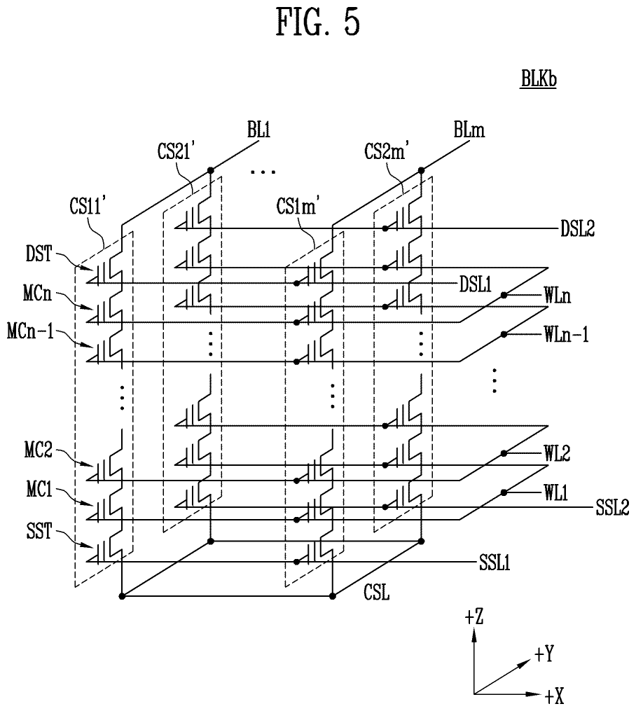

Referring to FIG. 3, the memory cell array 110 includes the plurality of memory blocks BLK1 to BLKz. Each memory block has a three-dimensional (3D) structure. Each of the memory blocks includes a plurality of memory cells stacked on a substrate. The plurality of memory cells are arranged in +X, +Y, and +Z directions. The structure of each memory block will be described in detail below with reference to FIGS. 4 and 5.

FIG. 4 is a circuit diagram illustrating any one of memory blocks of FIG. 3.

Referring to FIG. 4, a memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings may be arranged in a row direction (i.e., a positive (+) X direction). In FIG. 4, two cell strings are illustrated as being arranged in a column direction (i.e., a positive (+) Y direction). However, this illustration is made for convenience of description, and it will be understood that three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is connected between the common source line CSL and the memory cells MC1 to MCp.

In an embodiment, source select transistors of cell strings arranged in the same row are connected to a source select line extending in a row direction, and source select transistors of cell strings arranged in different rows are connected to different source select lines. In FIG. 4, source select transistors of the cell strings CS11 to CS1m in a first row are connected to a first source select line SSL1. Source select transistors of the cell strings CS21 to CS2m in a second row are connected to a second source select line SSL2.

In an embodiment, source select transistors of the cell strings CS11 to CS1m and CS21 to CS2m may be connected in common to one source select line.

The first to n-th memory cells MC1 to MCn in each cell string are connected between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are sequentially arranged in a direction opposite to a positive (+) Z direction and are connected in series between the source select transistor SST and the pipe transistor PT. The p+1-th to n-th memory cells MCp+1 to MCn are sequentially arranged in the +Z direction and are connected in series between the pipe transistor PT and the drain select transistor DST. The first to p-th memory cells MC1 to MCp and the p+1-th to n-th memory cells MCp+1 to MCn are connected to each other through the pipe transistor PT. Gates of the first to n-th memory cells MC1 to MCn of each cell string are connected to first to n-th word lines WL1 to WLn, respectively.

A gate of the pipe transistor PT of each cell string is connected to a pipeline PL.

The drain select transistor DST of each cell string is connected between the corresponding bit line and the memory cells MCp+1 to MCn. Drain select transistors DST of cell strings arranged in the row direction may be connected to drain select lines extending in the row direction. Drain select transistors of the cell strings CS11 to CS1m in the first row are connected to a first drain select line DSL1. Drain select transistors of the cell strings CS21 to CS2m in the second row are connected to a second drain select line DSL2.

Cell strings arranged in the column direction may be connected to bit lines extending in the column direction. In FIG. 4, cell strings CS11 and CS21 in the first column are connected to a first bit line BL1. Cell strings CS1m and CS2m in an m-th column are connected to an m-th bit line BLm.

Memory cells connected to the same word line in cell strings arranged in the row direction form a single page. For example, memory cells connected to the first word line WL1, among the cell strings CS11 to CS1m in the first row, form a single page. Memory cells connected to the first word line WL1, among the cell strings CS21 to CS2m in the second row, form another single page. Cell strings arranged in the direction of one row may be selected by selecting any one of the drain select lines DSL1 and DSL2. One page may be selected from the selected cell strings by selecting any one of the word lines WL1 to WLn.

In an embodiment, instead of the first to m-th bit lines BL1 to BLm, even bit lines and odd bit lines may be provided. Even-numbered cell strings, among the cell strings CS11 to CS1m or CS21 to CS2m arranged in a row direction, may be connected to respective even bit lines. Odd-numbered cell strings, among the cell strings CS11 to CS1m or CS21 to CS2m arranged in the row direction, may be connected to respective odd bit lines.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCp. Alternatively, in an embodiment, the one or more dummy memory cells are provided to reduce an electric field between the drain select transistor DST and the memory cells MCp+1 to MCn. In an embodiment, as the number of dummy memory cells that are provided is increased, the reliability of operation of the memory block BLKa may be improved, whereas the size of the memory block BLKa may be increased. In an embodiment, as the number of dummy memory cells that are provided is decreased, the size of the memory block BLKa may be decreased, whereas the reliability of operation of the memory block BLKa may be deteriorated.

In an embodiment, in order to efficiently control the one or more dummy memory cells, respective dummy memory cells may have required threshold voltages. Before or after an erase operation on the memory block BLKa is performed, program operations may be performed on all or some of the dummy memory cells. When the erase operation is performed after the program operations have been performed, the respective dummy memory cells may have required threshold voltages by controlling voltages to be applied to dummy word lines connected to respective dummy memory cells.

FIG. 5 is a circuit diagram illustrating an embodiment of any one of memory blocks of FIG. 3.

Referring to FIG. 5, a memory block BLKb may include a plurality of cell strings CS11′ to CS1m′ and CS21′ to CS2m′. Each of the cell strings CS11′ to CS1m′ and CS21′ to CS2m′ extends in a +Z direction. Each of the cell strings CS11′ to CS1m′ and CS21′ to CS2m′ includes at least one source select transistor SST, first to n-th memory cells MC1 to MCn, and at least one drain select transistor DST, which are stacked on a substrate (not illustrated) under the memory block BLKb.

The source select transistor SST of each cell string is connected between the common source line CSL and the memory cells MC1 to MCn. The source select transistors of cell strings arranged in the same row are connected to the same source select line. Source select transistors of the cell strings CS11′ to CS1m′ arranged in a first row may be connected to a first source select line SSL1. Source select transistors of the cell strings CS21′ to CS2m′ arranged in a second row may be connected to a second source select line SSL2. In an embodiment, source select transistors of the cell strings CS11′ to CS1m′ and CS21′ to CS2m′ may be connected in common to a single source select line.

The first to n-th memory cells MC1 to MCn in each cell string are connected in series between the source select transistor SST and the drain select transistor DST. Gates of the first to n-th memory cells MC1 to MCn are respectively connected to first to n-th word lines WL1 to WLn.

The drain select transistor DST of each cell string is connected between the corresponding bit line and the memory cells MC1 to MCn. Drain select transistors of cell strings arranged in the row direction may be connected to drain select lines extending in the row direction. Drain select transistors of the cell strings CS11′ to CS1m′ in the first row are connected to a first drain select line DSL1. Drain select transistors of the cell strings CS21′ to CS2m′ in the second row may be connected to a second drain select line DSL2.

Consequentially, the memory block BLKb of FIG. 5 may have an equivalent circuit similar to that of the memory block BLKa of FIG. 4 except that a pipe transistor PT is excluded from each cell string.

In an embodiment, instead of the first to m-th bit lines BL1 to BLm, even bit lines and odd bit lines may be provided. Even-numbered cell strings, among the cell strings CS11′ to CS1m′ or CS21′ to CS2m′ arranged in a row direction, may be connected to respective even bit lines. Odd-numbered cell strings, among the cell strings CS11′ to CS1m′ or CS21′ to CS2m′ arranged in the row direction, may be connected to respective odd bit lines.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, in an embodiment, the one or more dummy memory cells are provided to reduce an electric field between the drain select transistor DST and the memory cells MC1 to MCn. In an embodiment, as the number of dummy memory cells that are provided is increased, the reliability of operation of the memory block BLKb may be improved, whereas the size of the memory block BLKb may be increased. In an embodiment, as the number of dummy memory cells that are provided is decreased, the size of the memory block BLKb may be decreased, whereas the reliability of operation of the memory block BLKb may be deteriorated.

In an embodiment, in order to efficiently control the one or more dummy memory cells, respective dummy memory cells may have required threshold voltages. Before or after an erase operation on the memory block BLKb is performed, program operations may be performed on all or some of the dummy memory cells. When the erase operation is performed after the program operations have been performed, the respective dummy memory cells may have required threshold voltages by controlling voltages to be applied to dummy word lines connected to respective dummy memory cells.

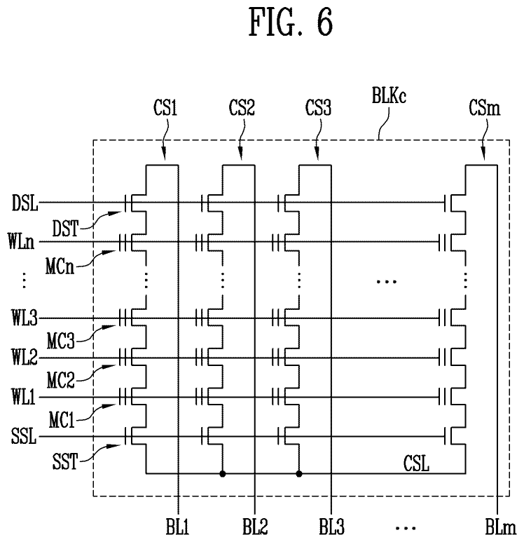

FIG. 6 is a circuit diagram illustrating an embodiment of any one of a plurality of memory cells included in the memory cell array of FIG. 2.

Referring to FIG. 6, a memory block BLKc may include a plurality of cell strings CS1 to CSm. The plurality of cell strings CS1 to CSm may be connected to a plurality of bit lines BL1 to BLm, respectively. Each of the cell strings CS1 to CS1m includes at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST in each cell string is connected between the common source line CSL and the memory cells MC1 to MCn.

The first to n-th memory cells MC1 to MCn in each cell string are connected between the source select transistor SST and the drain select transistor DST.

The drain select transistor DST in each cell string is connected between the corresponding bit line and the memory cells MC1 to MCn.

The memory cells connected to the same word line may constitute a single page. The cell strings CS1 to CSm may be selected by selecting the drain select line DSL. One page may be selected from the selected cell strings by selecting any one of the word lines WL1 to WLn.

In an embodiment, instead of the first to m-th bit lines BL1 to BLm, even bit lines and odd bit lines may be provided. Among the cell strings CS1 to CSm, even-numbered cell strings may be connected to the even bit lines, respectively, and odd-numbered cell strings may be connected to the odd bit lines, respectively.

As illustrated in FIGS. 3 to 5, the memory cell array 110 may be implemented as a memory cell array having a 3D structure. Further, as illustrated in FIG. 6, the memory cell array 110 may be implemented as a memory cell array having a 3D structure.

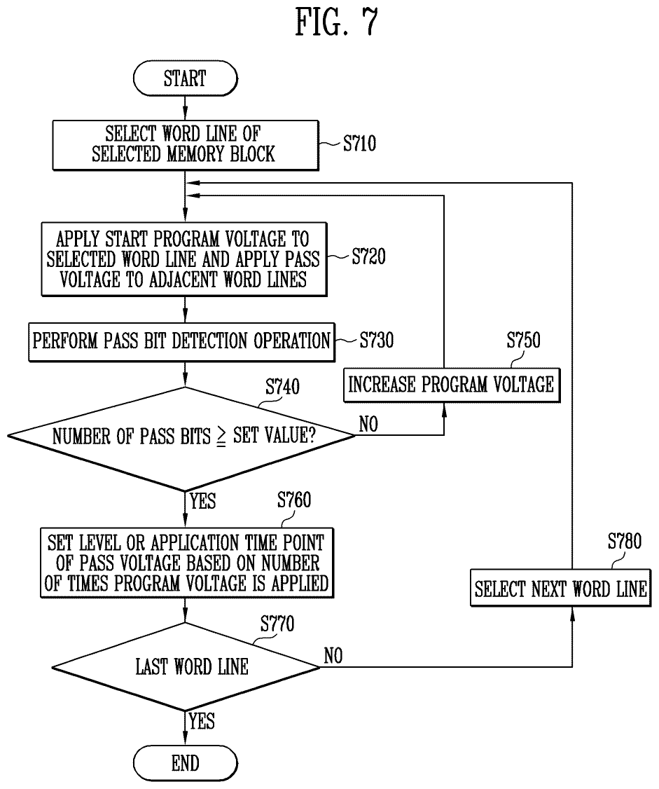

FIG. 7 is a flowchart for explaining the operation of a memory device according to an embodiment of the present disclosure.

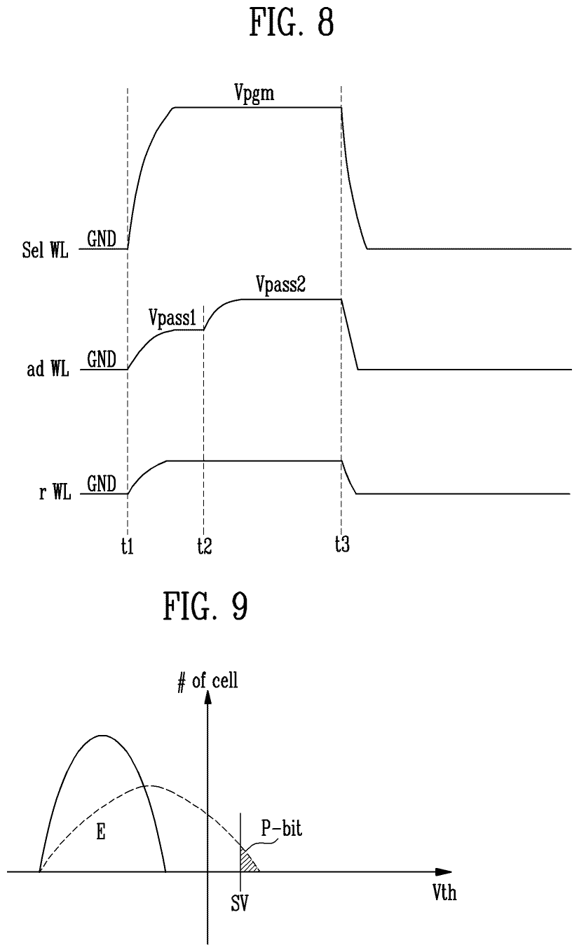

FIG. 8 is a waveform diagram of signals for explaining a program voltage apply operation among operations of a memory device according to an embodiment of the present disclosure.

FIG. 9 is a threshold voltage distribution diagram for explaining the threshold voltages of memory cells after a test program operation.

The method of operating the memory device according to various embodiments of the present disclosure will be described with reference to FIGS. 2 to 9.

At S710, in order to perform a test operation at S720, S730, S740, and S750, one memory block may be selected from among the plurality of memory blocks BLK1 to BLKz, and one word line may be selected from the selected one memory block. For example, a first word line WL1 of the memory block (e.g., BLK1) selected from among the plurality of memory blocks BLK1 to BLKz may be selected. Memory cells included in the selected memory block (e.g., BLK1) may have threshold voltages corresponding to an erase state E.

At S720, a test program operation may be performed on the selected word line WL1 of the selected memory block BLK1. For example, the program voltage Vpgm may be applied to the selected word line WL1, and the first pass voltage Vpass1 and the second pass voltage Vpass2 may be sequentially applied to the word line WL2 adjacent to the selected word line WL1.

The test operation controller 150 may control the peripheral circuit 120 to perform the test program operation on the selected word line WL1 of the selected memory block BLK1. For example, the voltage generator 122 may generate the program voltage Vpgm, the first pass voltage Vpass1, and the second pass voltage Vpass2 under the control of the test operation controller 150. The page buffer group 123 may apply a program-enable voltage to the plurality of bit lines BL1 to BLm under the control of the test operation controller 150.

The address decoder 121 may apply the program voltage Vpgm to the selected word line sel WL (e.g., WL1), and apply the first pass voltage Vpass1 to the adjacent word line ad WL (e.g., WL2) and the remaining word lines r WL (e.g., WL3 to WLn) during a first period from t1 to t2 under the control of the test operation controller 150. Thereafter, the address decoder 121 may apply the second pass voltage Vpass2 having a potential higher than that of the first pass voltage Vpass to the adjacent word line ad WL (e.g., WL2) during a second period from t2 to t3. A time point t2 at which the second pass voltage Vpass2 is applied may be an initially set time point. Further, the potential of the second pass voltage Vpass2 may be an initial value.

Accordingly, the threshold voltages of some memory cells among memory cells MC1 in an erase state E, which are connected to the selected word line sel WL (e.g., WL1) may increase.

At S730, a pass bit detection operation may be performed on the selected word line sel WL. The test operation controller 150 may detect memory cells having threshold voltages equal to or higher than a set threshold voltage SV among the memory cells connected to the selected word line sel WL on which the test program operation is performed.

The test operation controller 150 may control the peripheral circuit 120 to perform the pass bit detection operation on the selected word line sel WL. For example, the voltage generator 122 may generate a set read voltage and a read pass voltage, which correspond to the set threshold voltage SV, under the control of the test operation controller 150. The address decoder 121 may apply the set read voltage to the selected word line sel WL and apply the read pass voltage to the unselected word lines ad WL and r WL under the control of the test operation controller 150. The page buffer group 123 may detect memory cells having threshold voltages equal to or higher than the set threshold voltage SV among the memory cells connected to the selected word line sel WL by sensing the potential or the current amount of the bit lines BL1 to BLm, under the control of the test operation controller 150. The memory cells having threshold voltages equal to or higher than the set threshold voltage SV may correspond to pass bits P-bit.

At S740, the number of detected pass bits P-bit may be compared with a set value. For example, the first to m-th page buffers PB1 to PBm may output a sensing voltage VPB having a varying potential depending on the number of detected pass bits P-bit. The sensing circuit 125 may generate a reference current in response to an enable bit signal VRYBIT corresponding to the set value, and may generate a pass signal PASS or a fail signal FAIL by comparing the sensing voltage VPB with a reference voltage generated using the reference current. For example, the sensing circuit 125 may generate the pass signal PASS when the number of detected pass bits P-bit is equal to or greater than the set value, and may generate the fail signal FAIL when the number of detected pass bits P-bit is less than the set value.

The test operation controller 150 may determine, based on the pass signal PASS or the fail signal FAIL, whether the number of detected pass bits P-bit is equal to or greater than the set value.

When it is determined at S740 that the number of detected pass bits P-bit is less than the set value (in the case of “No”), a new program voltage may be set by increasing the program voltage Vpgm by a step voltage at S750, and a procedure from the above-described S720 may be re-performed or performed again.

When it is determined at the above-described S740 that the number of detected pass bits P-bit is equal to or greater than the set value (in the case of Yes), the operating voltage setting circuit 160 may set the level of the pass voltage to be used in the program operation or a time point at which the pass voltage is to be applied, based on the number of times the above-described S720 is performed, at S760.

For example, as illustrated in FIG. 8, during a period in which the program voltage Vpgm is applied to the selected word line Sel WL (e.g., WL1) in the program operation, the first pass voltage Vpass1 and the second pass voltage Vpass2 may be sequentially applied to the word line ad WL adjacent to the selected word line sel WL. In an embodiment of the present disclosure, the potential level of the second pass voltage Vpass2 used in the program operation or the time point t2 at which the second pass voltage Vpass2 is to be applied may be adjusted based on the number of times S720 is performed.

For example, as the number of times S720 is performed is greater than the reference number of times, the potential level of the second pass voltage Vpass2 may be set to be increased from an initial value, or alternatively, the time point t2 at which the second pass voltage Vpass2 is to be applied may be set to be advanced from an initial value. On the other hand, as the number of times S720 is performed is less than the reference number of times, the potential level of the pass voltage Vpass2 may be set to be decreased from the initial value or, alternatively, the time point t2 at which the second pass voltage Vpass2 is to be applied may be set to be delayed from the initial value.

Further, the operating voltage setting circuit 160 may set a start program voltage to be used in the program operation based on the number of times the above-described S720 is performed.

Information about the start program voltage, information about the level of the second pass voltage Vpass2, or information about the application time point of the second pass voltage Vpass2, which is set by the operating signal setting circuit 160, may be stored in a memory block defined as a system block or a CAM block, among the plurality of memory blocks BLK1 to BLKz.

At S770, whether the currently selected word line sel WL is the last word line of the selected memory block may be determined. When it is determined that the currently selected word line sel WL is the last word line (in the case of “Yes”), the operation may be terminated.

When it is determined at S770 that the currently selected word line sel WL is not the last word line (in the case of “No”), a word line next to the currently selected word line sel WL may be selected at S780, and a procedure from S720 may be re-performed or performed again.

In a foregoing embodiment of the present disclosure, although the operating voltage setting circuit 160 has been described as setting the information about the start program voltage corresponding to the selected word line, the information about the level of the second pass voltage, or the information about the application time point of the second pass voltage, the present disclosure is not limited thereto.

The present disclosure may define a plurality of word lines as a single word line group, may calculate program speed as an average value by performing a test operation on a word line group including a plurality of word lines, a memory block, or a plane including a plurality of memory blocks, and may set the potential of the start program voltage, the potential of the second pass voltage, or the application time point of the second pass voltage, which corresponds to the word line group, the memory block or the plane, depending on the result of the calculation.

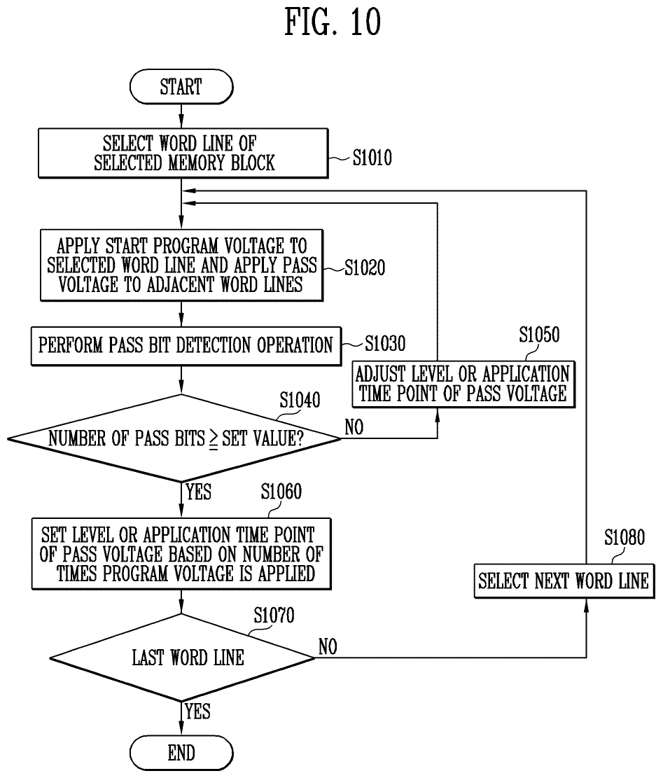

FIG. 10 is a flowchart for explaining the operation of a memory device according to an embodiment of the present disclosure.

The method of operating the memory device according to an embodiment of the present disclosure will be described with reference to FIGS. 2 to 6, 7, 8, and 9.

At S1010, in order to perform a test operation at S1020, S1030, S1040, and S1050, one memory block may be selected from among the plurality of memory blocks BLK1 to BLKz, and one word line may be selected from the selected one memory block. For example, a first word line WL1 of the memory block (e.g., BLK1) selected from among the plurality of memory blocks BLK1 to BLKz may be selected. Memory cells included in the selected memory block (e.g., BLK1) may have threshold voltages corresponding to an erase state E.

At S1020, a test program operation may be performed on the selected word line WL1 of the selected memory block BLK1. For example, the program voltage Vpgm may be applied to the selected word line WL1, and the first pass voltage Vpass1 and the second pass voltage Vpass2 may be sequentially applied to the word line WL2 adjacent to the selected word line Sel WL (e.g., WL1).

The test operation controller 150 may control the peripheral circuit 120 to perform the test program operation on the selected word line Sel WL (e.g., WL1) of the selected memory block BLK1. For example, the voltage generator 122 may generate the program voltage Vpgm, the first pass voltage Vpass1, and the second pass voltage Vpass2 under the control of the test operation controller 150. The page buffer group 123 may apply a program-enable voltage to the plurality of bit lines BL1 to BLm under the control of the test operation controller 150.

The address decoder 121 may apply the program voltage Vpgm to the selected word line sel WL (e.g., WL1), and apply the first pass voltage Vpass1 to the adjacent word line ad WL (e.g., WL2) and the remaining word lines r WL (e.g., WL3 to WLn) during a first period from t1 to t2 under the control of the test operation controller 150.

Thereafter, the address decoder 121 may apply the second pass voltage Vpass2 having a potential higher than that of the first pass voltage Vpass to the adjacent word line ad WL (e.g., WL2) during a second period from t2 to t3. A time point t2 at which the second pass voltage Vpass2 is applied may be an initially set time point. Further, the potential of the second pass voltage Vpass2 may be an initial value. Accordingly, the threshold voltages of some memory cells among memory cells MC1 in an erase state E, which are connected to the selected word line sel WL (e.g., WL1) may increase.

At S1030, a pass bit detection operation may be performed on the selected word line sel WL. The test operation controller 150 may detect memory cells having threshold voltages equal to or higher than a set threshold voltage SV among the memory cells connected to the selected word line sel WL on which the test program operation is performed.

The test operation controller 150 may control the peripheral circuit 120 to perform the pass bit detection operation on the selected word line sel WL. For example, the voltage generator 122 may generate a set read voltage and a read pass voltage, which correspond to the set threshold voltage SV, under the control of the test operation controller 150. The address decoder 121 may apply the set read voltage to the selected word line sel WL and apply the read pass voltage to the unselected word lines ad WL and r WL under the control of the test operation controller 150. The page buffer group 123 may detect memory cells having threshold voltages equal to or higher than the set threshold voltage SV among the memory cells connected to the selected word line sel WL by sensing the potential or the current amount of the bit lines BL1 to BLm, under the control of the test operation controller 150. The memory cells having threshold voltages equal to or higher than the set threshold voltage SV may correspond to pass bits P-bit.

At S1040, the number of detected pass bits P-bit may be compared with a set value. For example, the first to m-th page buffers PB1 to PBm may output a sensing voltage VPB having a varying potential depending on the number of detected pass bits P-bit. The sensing circuit 125 may generate a reference current in response to an enable bit signal VRYBIT corresponding to the set value, and may generate a pass signal PASS or a fail signal FAIL by comparing the sensing voltage VPB with a reference voltage generated using the reference current. For example, the sensing circuit 125 may generate the pass signal PASS when the number of detected pass bits P-bit is equal to or greater than the set value, and may generate the fail signal FAIL when the number of detected pass bits P-bit is less than the set value.

The test operation controller 150 may determine, based on the pass signal PASS or the fail signal FAIL, whether the number of detected pass bits P-bit is equal to or greater than the set value.

When it is determined at S1040 that the number of detected pass bits P-bit is less than the set value (in the case of “No”), a new second pass voltage Vpass2 may be set by increasing the potential of the second pass voltage Vpass2 by a step voltage at step S1050 or, alternatively, the time point t2 at which the second pass voltage Vpass2 is to be applied may be set to be advanced by a set time, after which a procedure from S1020 may be re-performed or performed again.

When it is determined at the above-described S1040 that the number of detected pass bits P-bit is equal to or greater than the set value (in the case of Yes), the operating voltage setting circuit 160 may set the level of the pass voltage to be used in the program operation or a time point at which the pass voltage is to be applied, based on the number of times the above-described S1020 is performed, at S1060.

For example, as illustrated in FIG. 8, during a period in which the program voltage Vpgm is applied to the selected word line WL1 in the program operation, the first pass voltage Vpass1 and the second pass voltage Vpass2 may be sequentially applied to the word line ad WL adjacent to the selected word line sel WL. In an embodiment of the present disclosure, the potential level of the second pass voltage Vpass2 used in the program operation or the time point t2 at which the second pass voltage Vpass2 is to be applied may be adjusted based on the number of times S1020 is performed.

For example, as the number of times S1020 is performed is greater than the reference number of times, the potential level of the second pass voltage Vpass2 may be set to be increased from an initial value, or alternatively, the time point t2 at which the second pass voltage Vpass2 is to be applied may be set to be advanced from an initial value. On the other hand, as the number of times S1020 is performed is less than the reference number of times, the potential level of the pass voltage Vpass2 may be set to be decreased from the initial value or, alternatively, the time point t2 at which the second pass voltage Vpass2 is to be applied may be set to be delayed from the initial value.

Further, the operating voltage setting circuit 160 may set a start program voltage to be used in the program operation based on the number of times the above-described S1020 is performed.

Information about the start program voltage, information about the level of the second pass voltage Vpass2, or information about the application time point of the second pass voltage Vpass2, which is set by the operating signal setting circuit 160, may be stored in a memory block defined as a system block or a CAM block, among the plurality of memory blocks BLK1 to BLKz.

At S1070, whether the currently selected word line sel WL is the last word line of the selected memory block may be determined. When it is determined that the currently selected word line sel WL is the last word line (in the case of “Yes”), the operation may be terminated.

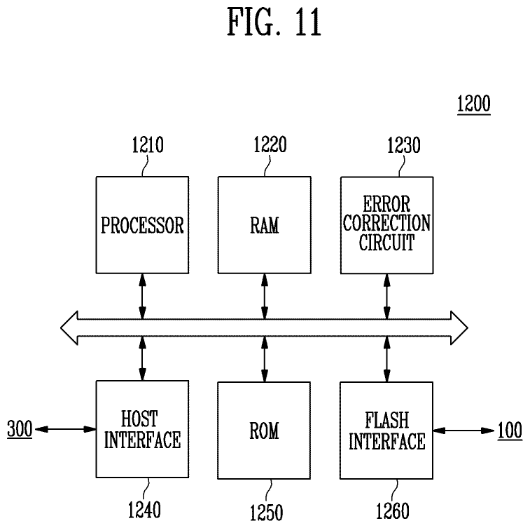

When it is determined at S1070 that the currently selected word line sel WL is not the last word line (in the case of “No”), a word line next to the currently selected word line sel WL may be selected at S1080, and a procedure from S1020 may be re-performed or performed again. FIG. 11 is a diagram for explaining the memory controller of FIG. 1.

The memory controller 1200 of FIG. 11 may represent the memory controller 200 of FIG. 2.

Referring to FIG. 11, the memory controller 1200 may include a processor 1210, a random access memory (RAM) 1220, an error correction circuit 1230, a host interface 1240, a read only memory (ROM) 1250, and a flash interface 1260.

The processor 1210 may control the overall operation of the memory controller 1200. The RAM 1220 may be used as a buffer memory, a cache memory or a working memory of the memory controller 1200.

The error correction circuit 1230 may perform error correction. The error correction circuit 1230 may perform error correction code (ECC) encoding based on data to be written to the memory device 100 through the flash interface 1260. The ECC-encoded data may be transferred to the memory device 100 through the flash interface 1260. The error correction circuit 1230 may perform ECC decoding on data received from the memory device 100 through the flash interface 1260. In an example, the error correction circuit 1230 may be included, as the component of the flash interface 1260, in the flash interface 1260.

The ROM 1250 may store various types of information required for operating the memory controller 1200 in the form of firmware.

The memory controller 1200 may communicate with an external device (e.g., the host 300, an application processor or the like) through the host interface 1240.

The memory controller 1200 may communicate with the memory device 100 through the flash interface 1260. The memory controller 1200 may transmit a command, an address, a control signal, or the like to the memory device 100 and receive data from the memory device 100, through the flash interface 1260. In an example, the flash interface 1260 may include a NAND interface.

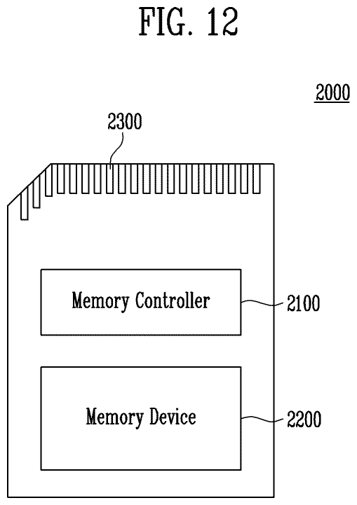

FIG. 12 is a block diagram illustrating a memory card system to which a memory system according to an embodiment of the present disclosure is applied.

Referring to FIG. 12, a memory card system 2000 includes a memory controller 2100, a memory device 2200, and a connector 2300.

The memory controller 2100 is connected to the memory device 2200. The memory controller 2100 may access the memory device 2200. For example, the memory controller 2100 may control read, write, erase, and background operations of the memory device 2200. The memory controller 2100 may provide an interface between the memory device 2200 and a host. The memory controller 2100 may run firmware for controlling the memory device 2200. The memory controller 2100 may be implemented in the same manner as the memory controller 200, described above with reference to FIG. 1. The memory device 2200 may be implemented in the same manner as the memory device 100, described above with reference to FIG. 1.

In an embodiment, the memory controller 2100 may include components, such as a RAM, a processor, a host interface, a memory interface, and an error correction circuit.

The memory controller 2100 may communicate with an external device through the connector 2300. The memory controller 2100 may communicate with an external device (e.g., a host) based on a specific communication standard. In an embodiment, the memory controller 2100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA), a serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 2300 may be defined by at least one of the above-described various communication standards.

In an embodiment, the memory device 2200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin transfer torque magnetic RAM (STT-MRAM).

The memory controller 2100 and the memory device 2200 may be integrated into a single semiconductor device to form a memory card. For example, the memory controller 2100 and the memory device 2200 may be integrated into a single semiconductor device to form a memory card such as a personal computer memory card international association (PCMCIA), a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

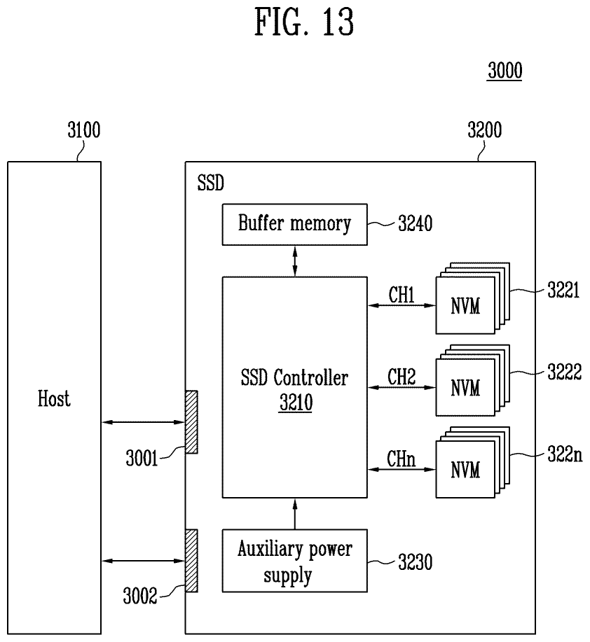

FIG. 13 is a block diagram illustrating a solid state drive (SSD) system to which a memory system according to an embodiment of the present disclosure is applied.

Referring to FIG. 13, an SSD system 3000 may include a host 3100 and an SSD 3200. The SSD 3200 may exchange signals with the host 3100 through a signal connector 3001, and may receive power through a power connector 3002. The SSD 3200 may include an SSD controller 3210, a plurality of flash memories 3221 to 322n, an auxiliary power supply 3230, and a buffer memory 3240.

In accordance with an embodiment of the present disclosure, the SSD controller 3210 may perform the function of the memory controller 200, described above with reference to FIG. 1.

The SSD controller 3210 may control the plurality of flash memories 3221 to 322n in response to the signals received from the host 3100. In an embodiment, the signals may be signals based on the interfaces of the host 3100 and the SSD 3200. For example, the signals may be signals defined by at least one of interfaces such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The auxiliary power supply 3230 may be connected to the host 3100 through the power connector 3002. The auxiliary power supply 3230 may be supplied with a supply voltage from the host 3100, and may be charged. The auxiliary power supply 3230 may supply the power of the SSD 3200 when the supply of power from the host 3100 is not performed. In an embodiment, the auxiliary power supply 3230 may be located inside the SSD 3200 or located outside the SSD 3200. For example, the auxiliary power supply 3230 may be located on a main board, and may provide auxiliary power to the SSD 3200.

The buffer memory 3240 functions as a buffer memory of the SSD 3200. For example, the buffer memory 3240 may store data received from the host 3100 or data received from the plurality of flash memories 3221 to 322n or may store metadata (e.g., mapping tables) of the flash memories 3221 to 322n. The buffer memory 3240 may include volatile memories, such as DRAM, SDRAM, DDR SDRAM, LPDDR SDRAM, and GRAM, or nonvolatile memories, such as FRAM, ReRAM, STT-MRAM, and PRAM.

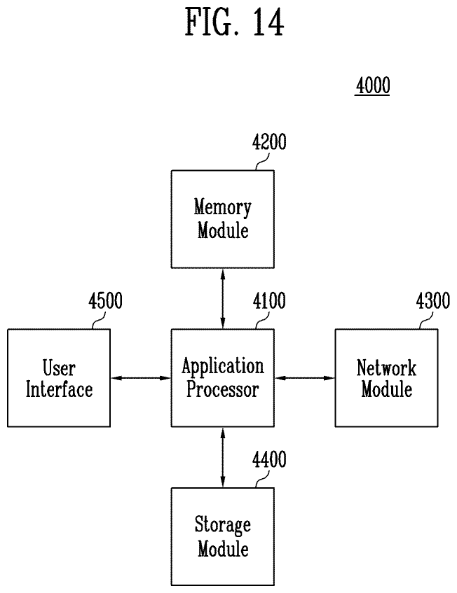

FIG. 14 is a block diagram illustrating a user system to which a memory system according to an embodiment of the present disclosure is applied.

Referring to FIG. 14, a user system 4000 may include an application processor 4100, a memory module 4200, a network module 4300, a storage module 4400, and a user interface 4500.

The application processor 4100 may run components included in the user system 4000, an operating system (OS) or a user program. In an embodiment, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDRAM, LPDDR2 SDRAM, and LPDDR3 SDRAM or nonvolatile RAMs such as PRAM, ReRAM, MRAM, and FRAM. In an embodiment, the application processor 4100 and the memory module 4200 may be packaged based on a package-on-package (POP), and may then be provided as a single semiconductor package.

The network module 4300 may communicate with external devices. In an embodiment, the network module 4300 may support wireless communication, such as code division multiple access (CDMA), global system for mobile communication (GSM), wideband CDMA (WCDMA), CDMA-2000, time division multiple access (TDMA), long term evolution (LTE), Wimax, WLAN, UWB, Bluetooth, or Wi-Fi. In an embodiment, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 4400 may be provided as a removable storage medium (removable drive), such as a memory card or an external drive of the user system 4000.

In an embodiment, the storage module 4400 may include a plurality of nonvolatile memory devices, each of which may be operated in the same manner as the memory device 100, described above with reference to FIG. 1. The storage module 4400 may be operated in the same manner as the memory system 50, described above with reference to FIG. 1.

The user interface 4500 may include interfaces which input data or instructions to the application processor 4100 or output data to external devices. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may include user output interfaces such as an a liquid crystal display (LCD), an organic light emitting diode (OLED) display device, an active matrix OLED (AMOLED) display device, an LED, a speaker, and a monitor.

According to various embodiments of the present disclosure, memory cells may be programmed to have a uniform threshold voltage distribution by compensating for variations in the program speed of the memory cells.

What is claimed is:

1. A memory device, comprising:
a memory block including a plurality of memory cells connected to a plurality of word lines, respectively;
a peripheral circuit configured to perform a test program operation and a pass bit detection operation of measuring a program speed of memory cells connected to a selected word line among the plurality of word lines during a test operation; and
control logic configured to control the peripheral circuit to perform the test operation, and set a potential of a pass voltage to be used in a program operation, or a time point at which the pass voltage is to be applied, based on a number of times the test program operation is performed.

2. The memory device according to claim 1, wherein the control logic comprises:
a test operation controller configured to control the peripheral circuit to perform the test operation; and
an operating voltage setting circuit configured to, when a number of memory cells having threshold voltages equal to or higher than a set threshold voltage value is equal to or greater than a set number as a result of the pass bit detection operation, set the potential of the pass voltage or the time point at which the pass voltage is to be applied, based on the number of times the test program operation is performed.

3. The memory device according to claim 1, wherein the peripheral circuit is configured to:
apply the program voltage to the selected word line during the test program operation, and
re-perform the test program operation when a number of pass bits corresponding to the number of memory cells programmed to have threshold voltages equal to or higher than the set threshold voltage value is less than a set number during the pass bit detection operation.

4. The memory device according to claim 3, wherein the control logic is configured to, when the number of pass bits is equal to or greater than the set number, set the potential of the pass voltage or the time point at which the pass voltage is to be applied, based on the number of times the test program operation is performed.

5. The memory device according to claim 4, wherein:
the pass voltage used in the program operation includes a first pass voltage and a second pass voltage that are sequentially applied, the second pass voltage having a potential higher than a potential of the first pass voltage, and
the control logic is configured to set the potential of the second pass voltage or a time point at which the second pass voltage is to be applied, based on the number of times the test program operation is performed.

6. The memory device according to claim 1, wherein the peripheral circuit comprises:
a voltage generator configured to generate operating voltages including a program voltage, a first pass voltage, a second pass voltage, a set read voltage, and a read pass voltage to be applied to the plurality of word lines;
an address decoder configured to transfer the operating voltages to the plurality of word lines; and
a page buffer group configured to apply a program-enable voltage to bit lines of the memory block during the test program operation, and detect memory cells programmed to have threshold voltages equal to or higher than a set threshold voltage among the memory cells connected to the selected word line through the bit lines during the pass bit detection operation.

7. The memory device according to claim 6, wherein the address decoder is configured to apply the program voltage to the selected word line, sequentially apply the first pass voltage and the second pass voltage to word lines adjacent to the selected word line, and apply the first pass voltage to remaining word lines during the test program operation.

8. The memory device according to claim 6, wherein the address decoder is configured to apply the set read voltage to the selected word line and apply the read pass voltage to remaining word lines during the pass bit detection operation.

9. A method of operating a memory device, comprising:
performing a test program operation on a selected word line among a plurality of word lines of a memory block;
detecting a number of pass bits corresponding to memory cells having threshold voltages equal to or higher than a set threshold voltage among memory cells connected to the selected word line by performing a pass bit detection operation;
wherein when the number of pass bits is less than a set value, re-performing the test program operation using a new program voltage; and
wherein when the number of pass bits is equal to or greater than the set value, setting a level of a pass voltage to be used in a program operation or a time point at which the pass voltage is to be applied, based on a number of times the test program operation is performed.

10. The method according to claim 9, wherein performing the test program operation comprises:
applying a program voltage to the selected word line;
sequentially applying a first pass voltage and a second pass voltage having a potential higher than a potential of the first pass voltage to word lines adjacent to the selected word line; and
applying the first pass voltage to remaining word lines, other than the selected word line and the adjacent word lines, among the plurality of word lines.

11. The method according to claim 10, wherein the new program voltage is a voltage increased from the program voltage used in the test program operation by a step voltage.

12. The method according to claim 10, wherein:
the pass voltage used in the program operation includes a first pass voltage and a second pass voltage that are applied to word lines adjacent to the selected word line, the second pass voltage having a potential higher than a potential of the first pass voltage, and
the first pass voltage and the second pass voltage are sequentially applied to the adjacent word lines.

13. The method according to claim 12, wherein setting the level of the pass voltage or the time point at which the pass voltage is to be applied comprises:
when the number of times the test program operation is performed is equal to or greater than a set number, resetting a potential of the second pass voltage by increasing the potential from a reference value, or resetting the time point at which the pass voltage is to be applied by advancing the time point from a reference time point.

14. The method according to claim 12, wherein setting the level of the pass voltage or the time point at which the pass voltage is to be applied comprises:
when the number of times the test program operation is performed is less than a set number, resetting a potential of the second pass voltage by decreasing the potential from a reference value, or resetting the time point at which the second pass voltage is to be applied by delaying the time point from a reference time point.

15. A method of operating a memory device, comprising:
performing a test program operation on a selected word line among a plurality of word lines of a memory block;
detecting a number of pass bits corresponding to memory cells having threshold voltages equal to or higher than a set threshold voltage among memory cells connected to the selected word line by performing a pass bit detection operation;
wherein when the number of pass bits is less than a set value, resetting a potential of a pass voltage to be applied to word lines adjacent to the selected word line or a time point at which the pass voltage is to be applied, and re-performing the test program operation; and
wherein when the number of pass bits is equal to or greater than the set value, setting a level of a pass voltage to be used in a program operation or a time point at which the pass voltage is to be applied, based on a number of times the test program operation is performed.

16. The method according to claim 15, wherein performing the test program operation comprises:
applying a program voltage to the selected word line;
sequentially applying a first pass voltage and a second pass voltage having a potential higher than a potential of the first pass voltage to the adjacent word lines; and
applying the first pass voltage to remaining word lines, other than the selected word line and the adjacent word lines, among the plurality of word lines.

17. The method according to claim 16, wherein resetting the potential of the pass voltage to be applied to the adjacent word lines or the time point at which the pass voltage is to be applied comprises:
resetting the potential of the second pass voltage by increasing the potential by a step voltage, or resetting a time point at which the second pass voltage is to be applied by advancing the time point by a set time.

18. The method according to claim 15, wherein:
the pass voltage used in the program operation includes a first pass voltage and a second pass voltage that are applied to word lines adjacent to the selected word line during the program operation, the second pass voltage having a potential higher than a potential of the first pass voltage, and
the first pass voltage and the second pass voltage are sequentially applied to the adjacent word lines.

19. The method according to claim 18, wherein setting the level of the pass voltage to be used in the program operation or the time point at which the pass voltage is to be applied comprises:
when the number of times the test program operation is performed is equal to or greater than a set number, resetting the potential of the second pass voltage by increasing the potential from a reference value, or resetting a time point at which the second pass voltage is to be applied by advancing the time point from a reference time point.

20. The method according to claim 18, wherein setting the level of the pass voltage to be used in the program operation or the time point at which the pass voltage is to be applied comprises:
when the number of times the test program operation is performed is less than a set number, resetting the potential of the second pass voltage by decreasing the potential from a reference value, or resetting a time point at which the second pass voltage is to be applied by delaying the time point from a reference time point.
